(19) United States
(12) Patent Application Publication
(10) Pub. No.: US 2018/0292457 A1
(43) Pub. Date: Oct. 11, 2018

(54) Method and Device for Analyzing an Electrical Circuit

(71) Applicant: Wistron NeWeb Corporation, Hsinchu (TW)

(72) Inventor: Yuan-Chia Hsu, Hsinchu (TW)

(21) Appl. No.: 15/672,324

(22) Filed: Aug. 9, 2017

(30) Foreign Application Priority Data
Apr. 7, 2017 (TW) 106111695

(51) Int. Cl. G01R 31/319; G01R 27/26; G01R 31/317; G01R 31/02; G01R 31/316; H04B 17/23

(52) U.S. Cl. CPC G01R 31/31912; G01R 27/2623; H04B 17/23; G01R 31/02; G01R 31/316; G01R 31/3171

(57) ABSTRACT

A method of analyzing an electrical circuit applied for an electrical system is disclosed. The method includes steps of obtaining a loss parameter and an eye diagram of a circuit channel of the electrical system; comparing the eye diagram with a standard eye diagram to generate a comparison result; generating an analytic result of the loss parameter according to the comparison result in order to adjust the eye diagram; and adjusting the loss parameter according to the analytic result.

### BACKGROUND OF THE INVENTION

### 1. Field of the Invention

The present invention relates to a method and device for analyzing an electrical circuit, and more specifically, to an analyzing method and an analyzing device for adjusting an eye diagram according to an analytical result of a circuit channel.

### 2. Description of the Prior Art

In an electronic system, an eye diagram is usually adopted as an index for determining the signal transmission characteristic between a transmitter and a receiver. Generally, stable transmission characteristic and less signal distortion lead to an eye diagram with greater eye opening, i.e. larger eye height and width. Hence, the eye diagram is a criterion for determining signal transmission process, and the eye height and the eye width are the critical indexes to the eye diagram.

In the prior art, there are two approaches to achieve good transmission characteristic. The first approach is to include a compensation circuit in the receiver, which raises the manufacturing cost, induces additional power consumption, and thus, is not suitable for a portable device requiring low power consumption. The second approach is to modify the transmission characteristic of a circuit channel between chips. In general, printed circuit boards (PCB) are usually adopted as the circuit channel between the chips for signaling. Impedance or loss information corresponding to the channel layout maybe obtained after the PCB layout is completed, and an eye diagram may be simulated according to the impedance information so as to determine the signal transmission characteristic corresponding to the channel layout. When the eye diagram does not meet system requirements, a circuit designer needs to modify the channel layout, perform the eye diagram simulation, and determine whether the signal transmission characteristic meets the system requirements, and repeats these processes until a circuit channel conforming to the system requirements is obtained. However, repeatedly modifying the channel layout and obtaining impedance information are time consuming and, even worse, such method may not meet the system requirements after a lot of time and efforts are devoted.

Therefore, how to analyze the electrical system and reduce the processes for modifying the channel layout so as to avoid meaningless adjustments and further improve the eye diagram is a significant objective in the field.

### SUMMARY OF THE INVENTION

It is therefore a primary objective of the present invention to provide a method and device for efficiently analyzing a circuit channel to adjust a loss parameter without modifying the circuit layout repeatedly to improve over the prior art.

An embodiment of the present invention discloses an analyzing method for analyzing an electrical circuit. The analyzing method is applied for an electrical system, and comprises obtaining a loss parameter and an eye diagram of a circuit channel in the electrical system; comparing the eye diagram with an expected eye diagram, for generating a comparison result; generating an analytical result corresponding to the loss parameter according to the comparison result, for adjusting the eye diagram; and adjusting the loss parameter according to the analytical result.

An embodiment of the present invention further discloses an electrical circuit analyzing device. The electrical circuit analyzing device is applied for an electrical system, and comprises a processing unit; and a storage unit, for storing a program code to instruct the processing unit to perform the following steps: obtaining a loss parameter and an eye diagram of a circuit channel in the electrical system; comparing the eye diagram with an expected eye diagram for generating a comparison result; generating an analytical result corresponding to the loss parameter according to the comparison result for adjusting the eye diagram; and adjusting the loss parameter according to the analytical result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an electrical system according to an embodiment of the present invention.

FIG. 2 is a schematic diagram of a process according to an embodiment of the present invention.

FIG. 3 is a schematic diagram of an eye diagram according to an embodiment of the present invention.

FIG. 4 is a schematic diagram of a process according to an embodiment of the present invention.

FIGS. 5A-5E are schematic diagrams of eye diagrams according to embodiments of the present invention.

FIG. 6 is a schematic diagram of a loss parameter according to an embodiment of the present invention.

### DETAILED DESCRIPTION

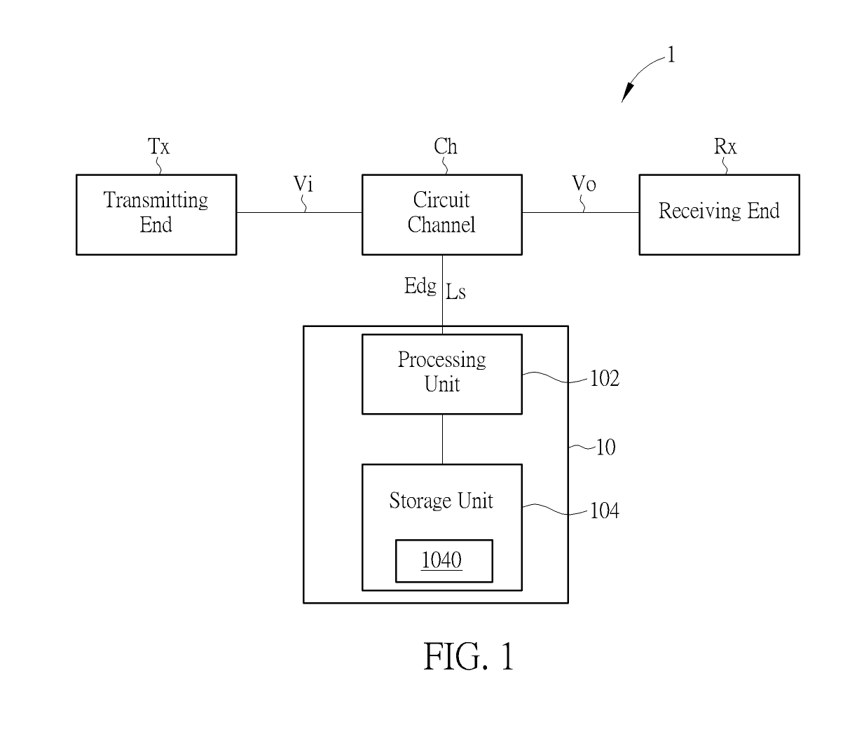

Please refer to FIG. 1, which is a schematic diagram of an electrical system 1 according to an embodiment of the present invention. In the electrical system 1, a transmitting end Tx outputs a digital signal Vi through a circuit channel Ch to a receiving end Rx. When the circuit channel Ch delivers the digital signal Vi from the transmitting end Tx to the receiving end Rx, the digital signal Vi changes to the digital signal Vo due to circuit characteristics (e.g., impedance, operating frequency, etc.) or non-ideal characteristics (e.g., jitter, decay, noise, etc.). To determine the signal quality of the electrical system 1, and especially the impact of the circuit channel Ch on the digital signal Vi, an eye diagram is generated by overlapping the digital signal Vi per signal cycle in one diagram. In order to ensure the circuit channel Ch to meet the system requirements, the embodiment of the present invention provides an electrical circuit analyzing device 10 to determine a plan for adjusting the electrical system 1.

The electrical circuit analyzing device 10 is coupled to the circuit channel Ch, and comprises a processing unit 102 and a storage unit 104. The processing unit 102 may be a microprocessor (MCU), application-specific integrated circuit (ASIC), etc., and is not limited herein. The storage unit 104 is configured for storing a program code 1040, which may be accessed and executed by the processing unit 102. The storage unit 104 may be any type of data storage device, e.g., a read-only memory, a random-access memory, an optical data storage device, a non-volatile memory, etc., and not limited herein.

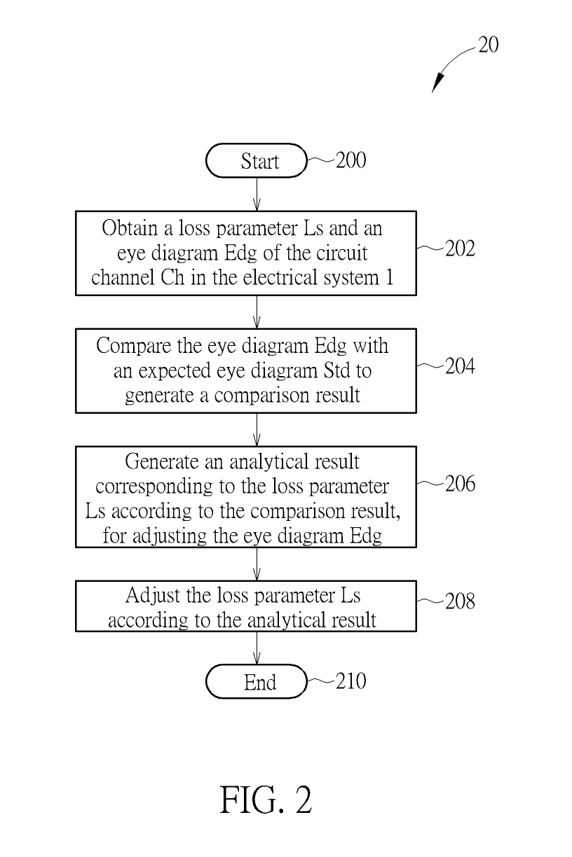

Please refer to FIG. 2, which is a schematic diagram of a circuit analyzing process 20 according to an embodiment of the present invention. The circuit analyzing process 20 is utilized for determining an adjusting plan of the electrical system 1, and may be compiled as the program code 1040 and executed by the processing unit 102. The circuit analyzing process 20 comprises the following steps:

Step 200: Start.

Step 202: Obtain a loss parameter Ls and an eye diagram Edg of the circuit channel Ch in the electrical system 1.

Step 204: Compare the eye diagram Edg with an expected eye diagram Std to generate a comparison result.

Step 206: Generate an analytical result corresponding to the loss parameter Ls according to the comparison result, for adjusting the eye diagram Edg.

Step 208: Adjust the loss parameter Ls according to the analytical result.

Step 210: End.

According to the electrical circuit analyzing process 20, the electrical circuit analyzing device 10 obtains the loss parameter Ls and the eye diagram Edg of the circuit channel Ch, compares the eye diagram Edg and the expected eye diagram Std to generate the comparison result, and generates the analytical result corresponding to the loss parameter Ls according to the comparison result, for adjusting the eye diagram Edg. The analytical result of the loss parameter Ls may be a direction for adjusting characteristics of the electrical system 1, to help the circuit designer to reduce repeated and meaningless attempts, and for providing analytical suggestions for adjusting the circuit so as to accelerate the design flow.

In detail, in order to analyze the signal transmission characteristic of the circuit channel Ch, the electrical circuit analyzing device 10 obtains the loss parameter Ls and the eye diagram Edg of the circuit channel Ch (i.e. Step 202), and determines the signal transmission characteristic of the circuit channel Ch according to the loss parameter Ls and the eye diagram Edg. Generally, the eye diagram Edg may be obtained by delivering a pseudo random binary sequence (PRBS) signal from the transmitting end Tx and overlapping the received signal at the receiving end Rx to observe the transmission characteristic of the circuit channel Ch. Note that, the loss parameter Ls may be related to a scattering parameter. Moreover, since the loss parameter Ls reflects transmission characteristics (e.g. frequency response, impedance, etc.) of the circuit channel Ch, the eye diagram Edg corresponding to the circuit channel Ch may be obtained by analyzing the loss parameter Ls, and is not limited within measuring the digital signal Vo.

Next, to determine whether the circuit channel Ch meets the system requirements, the obtained eye diagram Edg is compared with the expected eye diagram Std ruled by a transmission specification (Step 204). As known by one skilled in the art, a wide and clear eye opening of the eye diagram Edg represents good signal characteristic of the circuit channel Ch and little interference from the non-ideal effects. The expected eye diagram Std represents an eye diagram corresponding to a transmission quality satisfying the system requirements. Therefore, for ensuring that the circuit Ch meets the required transmission quality, the opening of the eye diagram Edg is required to conform to or be larger than the expected eye diagram Std. In such a situation, the present invention compares the eye diagram Edg and the expected eye diagram Std, to determine whether the circuit channel Ch meets the system requirements.

According to the comparison result of the eye diagram Edg and the expected eye diagram Std, the electrical circuit analyzing device 10 determines if the eye diagram Edg corresponding to the loss parameter Ls satisfies the system requirements, and generates the analytical result of the loss parameter Ls accordingly (i.e. Step 206), which may be taken as an indication for adjusting the circuit channel Ch. For example, if the eye diagram Edg cannot satisfy the system requirements, it represents that the non-idealities of the circuit channel Ch is dominant and degrades the signal quality. Since adjusting the loss parameter Ls may improve the non-idealities of the circuit channel Ch, the analytical result may include an indication for adjusting the loss parameter Ls, so as to improve the eye diagram Edg and enhance the signal quality of the circuit channel Ch.

In brief, the electrical circuit analyzing device 10 of the embodiment of the present invention obtains the loss parameter Ls and the eye diagram Edg of the circuit channel Ch, compares the eye diagram Edg with the expected eye diagram Std stored in the storage unit 104 to generate the comparison result, and generates the analytical result of the loss parameter Ls accordingly, where the analytical result may be used for adjusting the eye diagram Edg.

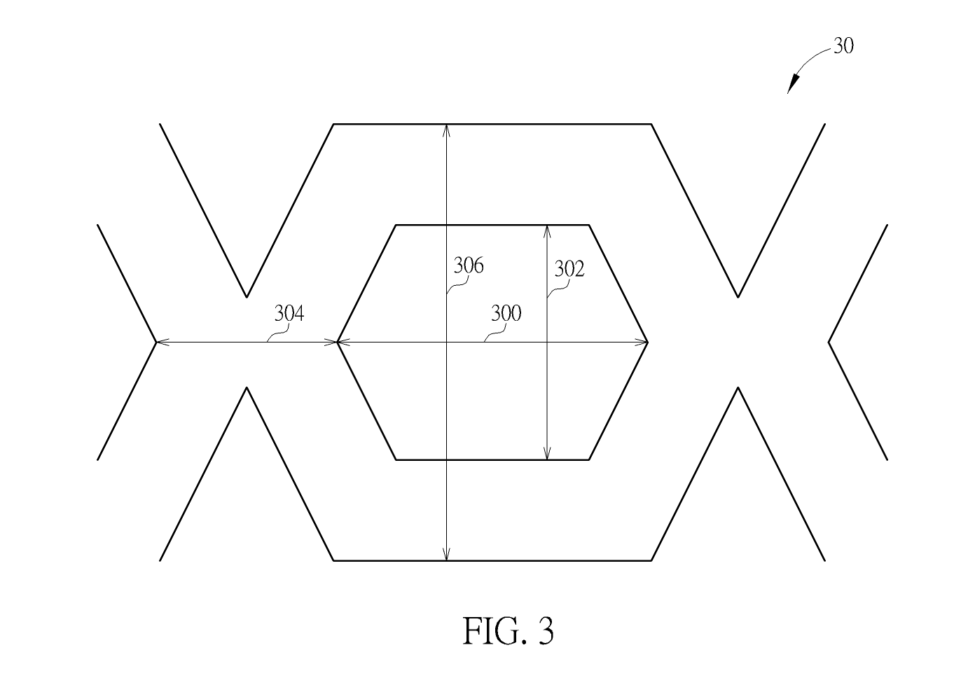

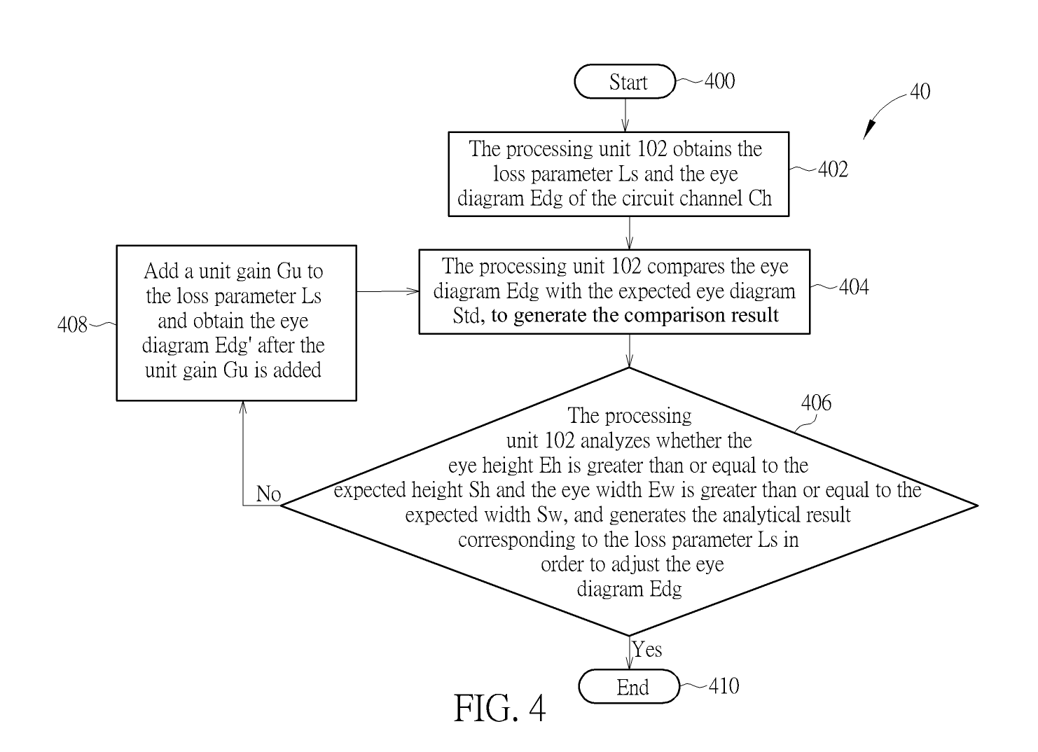

Notably, the electrical circuit analyzing process 20 is an embodiment of the present invention, those skilled in the art may make modifications and alterations accordingly, and not limited herein. For example, Step 204 is to compare the eye diagram Edg and the expected eye diagram Std, which may be realized by observing and comparing jitters, eye amplitudes, eye heights or eye widths of the eye diagrams. The eye height and the eye width are generally utilized as indexes for evaluating the eye diagram opening and may represent the signal quality. If values of the eye height and the eye width of the eye diagram are greater, the corresponding signal quality is more stable, such that the difficulty or error rate for the circuit to accurately determine the signals is lower. More specifically, please refer to FIG. 3, which is a schematic diagram of an eye diagram 30 according to an embodiment of the present invention. The eye diagram 30 includes information of an eye width 300, an eye height 302, a jitter 304, an amplitude 306, etc. which may be used for analyzing the eye opening, the clock synchronization and the noise impact on signal transmission in the circuit channel. As can be seen from FIG. 3, the eye width 300 and eye height 302 are directly related to the eye opening; thus, the present invention takes the eye width 300 and the eye height 302 as the indexes for determine whether the signal quality of the circuit channel Ch meets the system requirements. In other words, in Step 204, the electrical circuit analyzing device 10 may determine whether an eye height Eh and an eye width Ew of the eye diagram Edg are greater than an expected height Sh and an expected width Sw of the expected eye diagram Std. When the eye height Eh is greater than or equal to the expected height Sh and the eye width Ew is greater than or equal to the expected width Sw, the electrical circuit analyzing device 10 may determine there is no necessity to adjust the loss parameter Ls of the circuit channel Ch and generates a corresponding analytical result. On the other hand, when the eye height Eh is smaller than the expected height Sh and/or the eye width Ew is smaller than the expected width Sw, representing that the signal transmission quality of the circuit channel Ch does not meet the system specification and may lead to system errors when the receiving end Rx determines or processes the received signals, the analytical result generated by the electrical circuit analyzing device 10 may indicate to adjust the loss parameter Ls in order to adjust the eye diagram Edg. The steps mentioned above may be executed recursively by the electrical circuits until the eye height Eh is greater than or equal to the expected height Sh and the eye width Ew is greater than or equal to the expected width Sw. For example, a unit gain Gu may be added to the loss parameter Ls recursively for adjusting the loss parameter Ls to improve the signal transmission quality of the circuit channel Ch. The abovementioned operations may be summarized in a circuit analyzing and adjusting process 40, as shown in FIG. 4. The circuit analyzing and adjusting process 40 comprises the following steps:

Step 400: Start.

Step 402: The processing unit 102 obtains the loss parameter Ls and the eye diagram Edg of the circuit channel Ch.

Step 404: The processing unit 102 compares the eye diagram Edg with the expected eye diagram Std, to generate the comparison result.

Step 406: The processing unit 102 analyzes whether the eye height Eh is greater than or equal to the expected height Sh and the eye width Ew is greater than or equal to the expected width Sw, and generates the analytical result corresponding to the loss parameter Ls in order to adjust the eye diagram Edg. If yes, execute Step 410; if not, execute Step 408.

Step 408: Add a unit gain Gu to the loss parameter Ls and obtain the eye diagram Edg' after the unit gain Gu is added.

Step 410: End.

In the circuit analyzing and adjusting process 40, Steps 404, 406 and 408 may be regarded as a loss parameter adjusting loop. When the analytical result generated by the electrical circuit analyzing device 10 indicates to adjust the loss parameter Ls, the loss parameter adjusting loop may be repeatedly performed until the comparison result reveals that the eye height Eh is greater than or equal to the expected height Sh and the eye width Ew is greater than or equal to the expected width Sw.

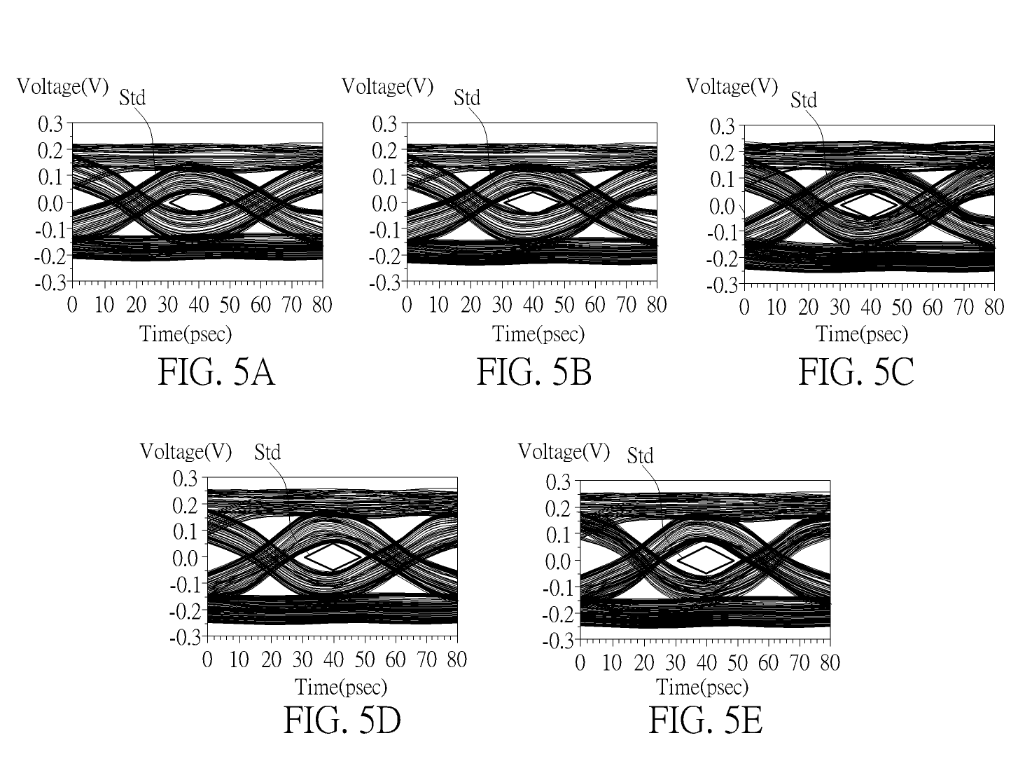

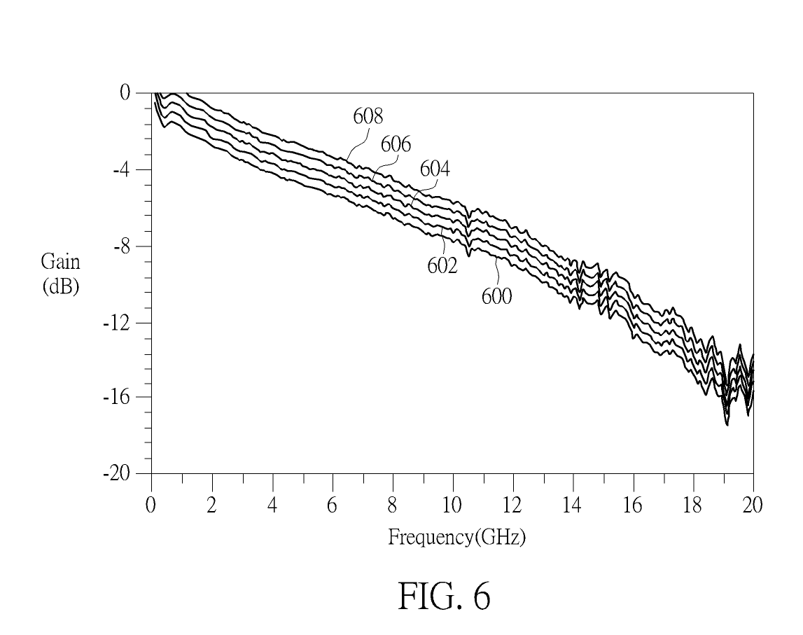

As to operating principles of the circuit analyzing and adjusting process 40, the following descriptions are illustrated together with FIGS. 5A-5E and FIG. 6, where the unit gain Gu is set as 0.5 dB. First, FIG. 5A is a schematic diagram of the eye diagram Edg of the circuit channel Ch in an initial state, which is the eye diagram Edg initially obtained by the electrical circuit analyzing device 10 according to the Step 402 (the electrical circuit analyzing device 10 also obtains the loss parameter Ls corresponding to the circuit channel Ch). As shown in FIG. 5A, the eye height Eh in the eye diagram Edg of the initial-state circuit channel Ch is smaller than the expected height Sh (i.e. the comparison result shown in Step 404). Thus, the analytic result generated by the electrical circuit analyzing device 10 in Step 406 indicates a situation that the transmission characteristic of the circuit channel Ch is not good enough to meet the system specification. Accordingly, circuit designers (or the processing unit 102) may add the unit gain Gu to the loss parameter Ls according to the analytical result and obtain a corresponding eye diagram Edg', as shown in FIG. 5B. The above procedure is a loss parameter adjusting loop.

Since the eye diagram Edg' shown in FIG. 5B does not satisfy the condition that the eye height Eh is required to be greater than or equal to the expected height Sh and the eye width Ew is required to be greater than or equal to the expected eye width Sw, the circuit designers (or the processing unit 102) may add the unit gain Gu to the loss parameter Ls according to the analytical result, to obtain the eye diagram shown in FIG. 5C. Repeating the above loss parameter adjusting loop may obtain the eye diagram shown in FIG. 5D, wherein the eye diagram shown in FIG. 5D satisfies the condition that the eye height Eh is greater than or equal to the expected height Sh and the eye width Ew is greater than or equal to the expected width Sw. Hence, the loss parameter adjusting loop is accomplished.

Furthermore, to enhance the signal transmission quality, the loss parameter adjusting loop maybe additionally executed according to the circuit analyzing and adjusting process 40. As shown in FIG. 5E, although the eye diagram shown in FIG. 5D already satisfies the system requirements, adding the unit gain Gu to the loss parameter Ls again may obtain an eye diagram with a greater eye opening compared to the expected eye diagram Std, so as to further decrease the error rate and reach a better signal transmission quality, which is within the scope of the present invention.

In another aspect, please refer to FIG. 6, which is a schematic diagram of the loss parameter Ls corresponding to the eye diagrams of FIGS. 5A-5E, where a curve 600 represents the loss parameter Ls obtained in the initial state and corresponding to the eye diagram shown in FIG. 5A, curves 602-608 respectively represent the loss parameter Ls corresponding to the eye diagram shown in FIGS. 5B-5E, which have executed the loss parameter adjusting loop for one to four times. As can be seen in FIG. 6, when the electrical circuit analyzing device 10 performs the loss parameter adjusting loop, each time the unit gain Gu is added to the loss parameter Ls, the loss parameter Ls and the eye diagram are altered, and the signal quality of the circuit channel Ch are improved, to meet the system specification.

Notably, the embodiments stated in the above are utilized for illustrating the concept of the present invention, and those skilled in the art may make modifications and alterations accordingly, which are not limited herein. For example, the processing unit 102 may not only increase the loss parameter Ls but also reduce the loss parameter Ls according to the analytical result instructed by the processing unit 102 when the eye diagram meets the system specification in order to decrease cost.

In another embodiment, except for performing the loss parameter adjusting loop, the loss parameter Ls may be adjusted by checking a lookup table. For example, after the processing unit 102 generates the analytical result of the loss parameter Ls, the processing unit 102 may check a predetermined lookup table with a difference value between the eye height Eh and the expected height Sh and/or between the eye width Ew and the expected width Sw, so as to determine the value for adjusting the loss parameter Ls.

In addition, to meet the system requirements and design flexibility, the processing unit 102 may not only compare the eye height Eh and eye width Ew of the eye diagram Edg with the expected height Sh and the expected width Sw of the expected eye diagram Std, but also compare the jitter or the amplitude of the eye diagram Edg to determine whether the circuit channel Ch meets the system specification and generate the analytical result accordingly.

Therefore, using the circuit analyzing and adjusting process 40 of the present invention, the circuit designers may execute the loss parameter adjusting loop according to the analytical result generated by the electrical circuit analyzing device 10, and adjust the eye diagram of the circuit channel Ch accordingly. The circuit designer may modify the layout of the circuit channel Ch right after the loss parameter which satisfies the system specification is obtained, unlike the prior art which modifies the circuit layout of the circuit channel Ch and generates the corresponding eye diagram Edg repeatedly without the instruction of the analytical result to determine whether the modified layout of the circuit channel Ch meets the system specification. Under such circumstances, according to the present invention, the circuit designer may save the expense of time from repeatedly modifying the layout of the circuit channel Ch and obtaining corresponding eye diagram Edg, and considerably shorten the design schedule and increase the design efficiency.

In the conventional art, when the transmission characteristic of the circuit channel does not meet the system specification, the circuit designers tend to modify the circuit layout for adjusting the transmission characteristic of the circuit, which may increase time for circuit design and decrease the design efficiency, because it is time consuming to obtain the loss parameter and the eye diagram from the circuit layout, and because there is no analytical result, the circuit designers have to blindly, meaninglessly and repeatedly modify the circuit layout to obtain the loss parameter which meets the system specification. In comparison, the electrical circuit analyzing device of the present invention may decrease invalid modification attempts for adjusting the circuit channel layout and further improve the eye diagram efficiently.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for analyzing an electrical circuit, applied for an electrical system, the method comprising:
obtaining a loss parameter and an eye diagram of a circuit channel in the electrical system;
comparing the eye diagram with an expected eye diagram, for generating a comparison result;
generating an analytical result corresponding to the loss parameter according to the comparison result, for adjusting the eye diagram; and
adjusting the loss parameter according to the analytical result.

2. The method of claim 1, wherein the step of comparing the eye diagram with the expected eye diagram for generating the comparison result comprises:
obtaining an eye height and an eye width of the eye diagram and an expected eye height and an expected eye width of the expected eye diagram; and
comparing the eye height and the eye width of the eye diagram with the expected eye height and expected eye width of the expected eye diagram, to generate the comparison result.

3. The method of claim 1, wherein the step of generating an analytical result corresponding to the loss parameter according to the comparison result comprises:
generating the analytical result of adjusting the loss parameter of the circuit channel when the comparison result indicates at least one of the eye height is smaller than the expected eye height and the eye width is smaller than the expected eye width; and
generating the analytical result of maintaining the loss parameter of the circuit channel when the comparison result indicates that the eye height is greater than or equal to the expected eye height and the eye width is greater than or equal to the expected eye width.

4. The method of claim 1, wherein when adjusting the loss parameter according to the analytical result, if the comparison result indicates at least one of the eye height is smaller than the expected eye height and the eye width is smaller than the expected eye width, a loss parameter adjusting loop is repeatedly performed until the comparison result indicates that the eye height is greater than or equal to the expected eye height and the eye width is greater than or equal to the expected eye width.

5. The method of claim 4, wherein the loss parameter adjusting loop is adding a unit gain to the loss parameter of the circuit channel, and comparing the eye diagram of the circuit channel with the expected eye diagram after the unit gain is added, to generate the comparison result.

6. The method of claim 1, wherein the loss parameter is a scattering parameter.

7. An electrical circuit analyzing device, applied for an electrical system, comprising:
a processing unit; and
a storage unit, for storing a program code to instruct the processing unit to perform the following steps:
obtaining a loss parameter and an eye diagram of a circuit channel in the electrical system;
comparing the eye diagram with an expected eye diagram for generating a comparison result;
generating an analytical result corresponding to the loss parameter according to the comparison result for adjusting the eye diagram; and
adjusting the loss parameter according to the analytical result.

8. The electrical circuit analyzing device of claim 7, wherein the processing unit is further configured to perform the following steps, for comparing the eye diagram with the expected eye diagram for generating the comparison result:
obtaining an eye height and an eye width of the eye diagram and an expected eye height and an expected eye width of the expected eye diagram; and
comparing the eye height and the eye width of the eye diagram with the expected eye height and expected eye width of the expected eye diagram, to generate the comparison result.

9. The electrical circuit analyzing device of claim 7, wherein the processing unit is further configured to perform the following steps, for generating an analytical result corresponding to the loss parameter according to the comparison result:
generating the analytical result of adjusting the loss parameter of the circuit channel when the comparison result indicates at least one of the eye height is smaller than the expected eye height and the eye width is smaller than the expected eye width; and
generating the analytical result of maintaining the loss parameter of the circuit channel when the comparison result indicates that the eye height is greater than or equal to the expected eye height and the eye width is greater than or equal to the expected eye width.

10. The electrical circuit analyzing device of claim 7, wherein when adjusting the loss parameter according to the analytical result, if the comparison result indicates at least one of the eye height is smaller than the expected eye height and the eye width is smaller than the expected eye width, the processing unit performs a loss parameter adjusting loop repeatedly until the comparison indicates that the eye height is greater than or equal to the expected eye height and the eye width is greater than or equal to the expected eye width.

11. The electrical circuit analyzing device of claim 10, wherein the loss parameter adjusting loop is performed by the processing unit to add a unit gain to the loss parameter of the circuit channel, and compare the eye diagram of the circuit channel with the expected eye diagram after the unit gain is increased, to generate the comparison result.
